(19) United States
(12) Patent Application Publication
(10) Pub. No.: US 2009/0183679 A1
(43) Pub. Date: Jul. 23, 2009

(54) ION SOURCE GAS REACTOR

(76) Inventors: Edward McIntyre, Franklin, MA (US); Richard Goldberg, Boston, MA (US)

Correspondence Address: KATTEN MUCHIN ROSENMAN LLP;(C/O PATENT ADMINISTRATOR), 2900 K STREET NW, SUITE 200, WASHINGTON, DC, 20007-5118, US

(21) Appl. No.: 12/357,538

(22) Filed: Jan. 22, 2009

Related U.S. Application Data
(60) Provisional application No. 61/022,562, filed on Jan. 22, 2008.

(51) Int. Cl. C23C 16/452; B01J 19/00; B01J 19/26

(52) U.S. Cl. 118/723 CB; 422/186

(57) ABSTRACT

An ion source is disclosed which includes a gas reaction chamber. The invention also includes a method of converting a gaseous feed material into a tetramer, dimer, other molecule or atomic species by supplying the feed material to the gas reaction chamber wherein the feed material is converted to the appropriate gas species to be supplied to the ion source and ionized. More particularly, the gas reaction chamber is configured to receive hydride and other feed materials in gaseous form, such as, AsH₃ or PH₃, and generate various molecular and atomic species for use in ion implantation, heretofore unknown. In one embodiment of the invention, the gas is relatively uniformly heated to provide relatively accurate control of the molecular or atomic species generated. In an alternate embodiment of the invention, the gas reaction chamber uses a catalytic surface to convert the feed gas into the different source gas specie required for implantation, such as, hydrides into tetramer molecules. In yet another embodiment of the invention, the gas reaction chamber is configured so that a catalytic (or pyrolytic) reaction occurs in the presence of an appropriate material including glass or metals such as, W, Ta, Mo, stainless steel, ceramics, boron nitride or other refractory metals, raised to an appropriate temperature.

### CROSS REFERENCE TO RELATED APPLICATIONS

This application claims priority to and the benefit of U.S. Provisional Patent Application No. 61/022,562, filed on Jan. 22, 2008, hereby incorporated by reference.

### BACKGROUND OF THE INVENTION

1. Field of the Invention

The present invention relates to gas reaction chamber which feeds an ion source for use in ion implantation of semiconductors and more particularly to a gas reaction chamber which converts gaseous materials into a particular gas feed material for ion beam production, for example, conversion of molecular gas material into other molecular or atomic species.

2. Description of the Prior Art

Ion implantation is a key enabling technology in the manufacture of integrated circuits (IC's). In the manufacture of logic and memory IC's, ions are implanted into substrates, formed from, for example, silicon and GaAs wafers, to form the transistor junctions. Ions are also implanted to dope the well regions of the pn junctions. By varying the energy of the ions, the implantation depth of the ions into the substrate can be controlled, allowing three-dimensional control of the dopant concentrations introduced by ion implantation. The dopant concentrations control the electrical properties of the transistors, and hence the performance of the IC's.

A number of different electrically active materials are known to be used as dopant materials including As, B, P, In, Sb, Bi and Ga. Many of these materials are available in gaseous form, for example as AsH₃, PH₃, BF₃, and SbF₅.

Known ion implanters are manufacturing tools which ionize the dopant-containing feed materials, (e.g., by an arc plasma, electron impact, RF or microwave, as is well known in the art,) and extract the dopant ions of interest; accelerate the dopant ion to the desired energy; filter away undesired species; and then transport the dopant ion of interest to the wafer. In order to achieve the desired implantation profile, the following variables must be controlled for a given implantation process:

Dopant feed material (e.g., BF₃ gas)

Dopant ion (e.g., B⁺)

Ion energy (e.g., 5 keV)

Chemical purity of the ion beam (e.g., <1% contaminants)

Energy purity of the ion beam (e.g., <2% FWHM)

ion dose, temperature and angular uniformity during implant.

An area of great importance in the technology of ion implantation is the ion source. The “standard” technology for commercial ion sources, namely the “Enhanced Bernas” ion source is well known. This type of source is commonly used in high current, high energy, and medium current ion implanters. The ion source is mounted to the vacuum system of the ion implanter, e.g., through a mounting flange which may also accommodate vacuum feed-throughs for cooling water, thermocouples, dopant gas feed, N₂ cooling gas, and power. A feed gas is fed into the source arc chamber in which the gas is cracked and or ionized to form the dopant ions.

The feed gas is frequently a material which is a gas under normal conditions. In some cases, the gas feed is derived from hot solid materials. In these cases, the gas feeding system includes a vaporizer or oven depending upon the type of solid feed material to be converted to a gas for introduction into the ion source chamber for ionization. Vaporizers or ovens (hereinafter referred to as “vaporizers”) are typically provided in which solid feed materials such as As, Sb₂O₃, B₁₈H₂₂, B₁₀H₁₄, C₁₄H₁₄ C₁₆H₁₀ and P are vaporized,

In one example known in the art, the ovens, gas feed, and cooling lines are contained within a cooled machined aluminum block. The water cooling is required to limit the temperature excursion of the aluminum block while the vaporizers, which operate between 100 C. and 800 C., are active, and also to counteract radiative heating by the arc chamber when the source is active. The arc chamber is mounted to, but in poor thermal contact with, the aluminum block.

Traditionally, Bernas-type ion sources have been used in ion implantation equipment. Bernas-type ion sources are known as hot plasma or arc discharge sources and typically incorporate an electron emitter, either a naked filament cathode or an indirectly-heated cathode. This type of source generates a plasma that is confined by a magnetic field. Recently, cluster implantation ion sources have been introduced into the equipment market place. These cluster ion sources are unlike the Bernas-style sources in that they have been designed to produce “clusters”, or conglomerates of dopant atoms in molecular form, including ions of the form Asₙ⁺, Pₙ⁺, CₙHₘ or BₙHₘ⁺, where n and m are integers, and m,n≧1. Such ionized clusters can be implanted much closer to the surface of a substrate and at higher dose rates relative to their monomer (n=1,m=0) counterparts. Therefore, cluster ion sources are of great interest for forming ultra-shallow p-n transistor junctions, for example, in transistor devices of the 65 nm, 45 nm, or 32 nm generations. For example, the method of cluster implantation and cluster ion sources is described in detail in U.S. Pat. Nos. 6,452,338; 6,686,595; 6,744,214 and 7,107,929, all hereby incorporated by reference. These cluster ion sources preserve the parent molecules (or utilize a different species thereof, e.g., C₁₄H₁₄ converts to C₇H₇) of the feed gases introduced into the ion source in generating the ion beam. The use of As₄⁺, P₄⁺or P₇⁺ as an implant material for ion implantation in making semiconductor devices is disclosed in applicant's assignee's pending U.S. patent application Ser. No. 60/856,994, incorporated by reference. Other materials for use in implantation may include CₙHₘ and As₇.

The vaporizers disclosed in the prior art, such as the above-identified patents, are suitable for vaporizing solid materials, such as decaborane (B₁₀H₁₄), C₁₄H₁₄, C₁₆H₁₀, B₁₈H₂₂ and TMI (trimethyl indium), which have relatively high vapor pressures at room temperature, and thus vaporize at temperatures around 100° C. The ovens traditionally associated with the Bernas type sources typically operate at temperatures greater than 100° C., e.g. from 100° C. to 800° C., due to the feed material to be converted to a gas for introduction into the ion source.

As known in the prior art, gaseous material may be fed directly into the ion source chamber, however, the feed material of interest in connection with semiconductor manufacturing purposes in gaseous form is limited. With regard to feed materials such as arsenic and phosphorous, a gaseous form, e.g., a hydride, is available for use in monomer atom implantation purposes. However, tetramer beams have been shown to be of interest with regard to efficiency of operation of the semiconductor manufacturing facility and may also offer process benefits. At present, tetramers, such as, As₄, P₄, and others, are difficult to create in standard Bernas type sources.

In the case of gaseous feed materials, such as, AsH₃ and PH₃, being used as a feed material in a Bernas type ion source, monomer forms of the dopant molecules are available in the ionization chamber, and so the formation of the tetramer molecule is known to be suppressed. To the extent a tetramer is formed, it is likely to be formed from metallic As (or P) deposited on walls of the ionization chamber which then forms the tetramer. The chamber walls are likely very hot or very cold with respect to the usual 350-400° C. vaporization temperatures used in ovens and hence the walls are not a very copious or repeatable source of tetramer molecules, e.g. As₄ or P₄.

Currently, the most generous source for generating tetramer molecules is known to be a vaporizer oven, operated at 350-400° C. with solid arsenic (As) or solid phosphorus (P). The major inadequacies of this method are numerous, including:

requirements to handle toxic or flammable materials in loading the oven;

slow heat up and cool down times of the materials, which affects the overall responsiveness of the system and tool throughput;

non-repeatability of the system, that is, different temperatures are often needed to reach the same operating pressures as the supply of feed material in the oven ages and the pressure can vary over short time periods depending on the nature of the solid feed material surface (e.g. native oxide layers) or even trapped volumes of gas which release at unpredictable times;

deposition of non-volatile, toxic or flammable metals on vacuum surfaces, which affects time of operation when cleaning of the oven inputs to the chamber is required; and

the inability to readily control, i.e., turn on and shut-off the flow of the tetramer material to the ion source chamber.

Molecular beam epitaxy (MBE) equipment is known which utilizes gaseous hydrides as a feed material. See, for example, Calawa, A. R., Applied Physics Letters (1981), 38(9), p. 701-703; Shiralagi, K. T., J. Vac. Sci. Technol. A (1992) 10(1), p 46-50; Panish, M. B., Prog. Crystal Growth and Charact. (1986) 12, p. 1-28; “Dimer and Tetramer Formation in an AsH3 Cracker Studied by Calibrated Quadrupole Mass Spectrometry”, C. Lohe and C. D. Kohl, J. Vac. Sci. Techno. B7 (2) March/April 1998; and “Gas Crackers” by Veeco, Compound Semiconductor, MBE Operations, St. Paul, Minn., USA.

In such systems, hydrides in gaseous form are used as feed materials. In order to generate molecular and atomic species of interest, “crackers” are known for “cracking” the gaseous hydride material into various molecular and atomic species. Such “crackers” are known to be ovens or furnaces which operate at temperatures in the range 800° K to 1300° K and which heat the gaseous hydrides producing various molecular and atomic species, including H₂, As₄, As₂, As, AsH and AsH₃ in the case of solid As material.

In the case of gaseous feed materials (AsH₃ and PH₃) primarily monomer forms are available in the ionization chamber, and so the formation of the four-fold tetramer molecule is suppressed. To the extent it happens, it is likely to be from metallic As (or P) deposited on walls which then form the tetramer. The chamber walls are likely very hot or very cold with respect to the usual 350-400° C. vaporization temperatures used in ovens and hence the walls are not a very copious or repeatable source of tetramer molecules (As₄ or P₄). Currently, the most generous source of tetramer molecules is a solid oven, operated at 350-400° C. with lump As or phosphorus.

The major inadequacies of this method are numerous, including: requirements to handle toxic or flammable materials in loading the oven; slow heat up and cool down times of the materials, which affects the overall responsiveness of the system and tool throughput; non-repeatability of the system, that is, different temperatures are often needed to reach the same operating pressures as the supply of feed material in the oven ages and the pressure can vary over short time periods depending on the nature of the solid feed material surface (e.g. native oxide layers) or even trapped volumes of gas which release at unpredictable times; deposition of non-volatile, toxic or flammable metals on vacuum surfaces, which affects time of operation when cleaning of the oven inputs to the chamber is required; and the inability to readily control, i.e., turn on and shut-off the flow of the tetramer material to the ion source chamber.

In order to generate atomic arsenic, the system disclosed in the '407 utilizes a two (2) step process that includes a vaporizer oven and a “cracker” which includes an atomizer to achieve the desired atomic species. More particularly, the arsenic atoms are produced in two steps. In the first step, a sublimator vaporizes solid arsenic, producing a molecular beam of arsenic tetramers and/or dimers. The molecular beam source can optionally include a cracker to produce As₂ from As₄. In the second step, the molecular beam impinges on a surface of a heated element, termed an atomizer, producing an output beam containing atomic arsenic.

The system disclosed in the '407 has several disadvantages. For example, it requires two (2) steps. That system also requires a vaporizer in addition to a cracker and is unsuitable for use with gaseous hydride materials.

Thus, there is a need for a system for use with gaseous hydrides to generate tetramer source materials that can be accomplished in a single step without the need for a separate vaporizer oven, which overcomes the problems associated with prior art methods for converting gaseous hydrides into various molecular and atomic species.

### SUMMARY OF THE INVENTION

Briefly, the present invention relates to an ion source which includes a gas reaction chamber. The invention also includes a method of converting a gaseous feed material into a tetramer, dimer, other molecule or atomic species by supplying the feed material to the gas reaction chamber wherein the feed material is converted to the appropriate gas species to be supplied to the ion source and ionized. More particularly, the gas reaction chamber is configured to receive hydride and other feed materials in gaseous form, such as, AsH₃ or PH₃, and generate various molecular and atomic species for use in ion implantation, heretofore unknown. In one embodiment of the invention, the gas is heated to provide relatively accurate control of the molecular or atomic species generated. In an alternate embodiment of the invention, the gas reaction chamber uses a catalytic surface to convert the feed gas into the different source gas specie required for implantation, such as, hydrides into tetramer molecules. In yet another embodiment of the invention, the gas reaction chamber is configured so that a catalytic or thermodynamic or pyrolytic reaction (herein catalytic) occurs in the presence of an appropriate material including glass or metals such as, W, Ta, Mo stainless steel, ceramics, boron nitride or other refractory metals, raised to an appropriate temperature.

The present invention provides various advantages over the prior art. For example, the invention allows the gaseous feed material to be handled with safety and easily with common practice, for example, with a safe delivery system, such as a gas cylinder. The invention also resolves problems associated with the prior art including providing responsive start up and shut down times as the delivery of the ion source gas stops when the feed gas is removed, the repeatability of the delivery rate is good since it depends on the gas feed rate and the build up of solid materials in the ionization chamber and vacuum system may be less due to the on-demand conversion of the feed material to the source material, e.g., hydrides into tetramers, rather than the slower heating and cooling of solids.

### DESCRIPTION OF THE DRAWING

These and other advantages of the present invention will be readily understood with reference to the following specification and attached drawing wherein:

FIG. 1 illustrates a schematic of a prior art ion source including a vaporizer.

FIG. 2 is a schematic of an embodiment of a gas reaction chamber in accordance with the present invention and a traditional oven feeding an ionization chamber.

FIG. 3 is a schematic of an embodiment of the ion and the gas reaction chamber in accordance with the present invention

### DETAILED DESCRIPTION

The present invention relates to an ion source which includes a gas reaction chamber or reactor. The gas reaction chamber is configured to receive hydride feed materials in gaseous form of hydrides, for example, AsH₃ or PH₃, and generate various molecular and atomic species for use in ion implantation, heretofore unknown. More particularly, the gas reaction chamber converts feed supply gases, such as, but not limited to hydrides, (e.g., AsH₃ or PH₃) into tetramers (As₄ or P₄), dimers or other desirable monomer or molecular species for implant in a single step without the use of a separate vaporizer oven.

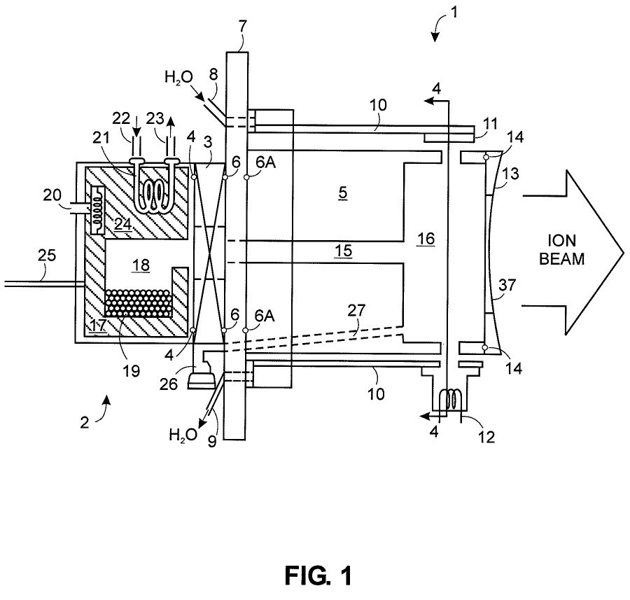

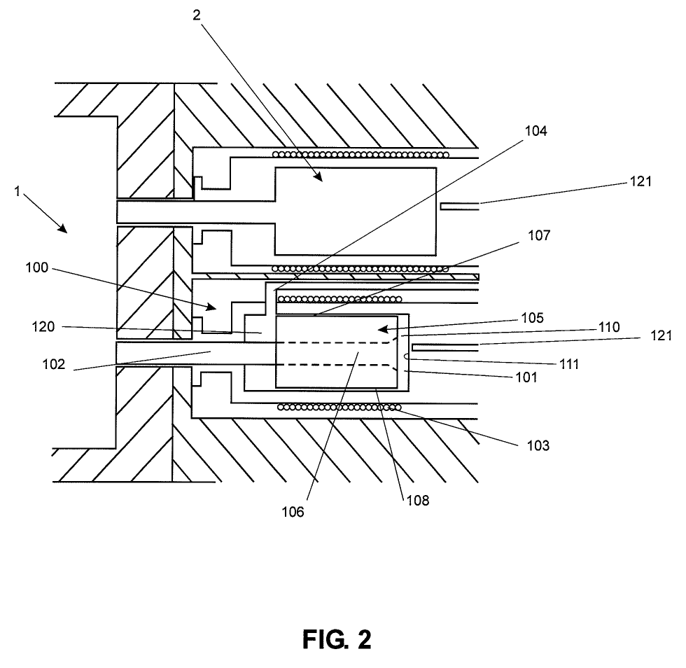

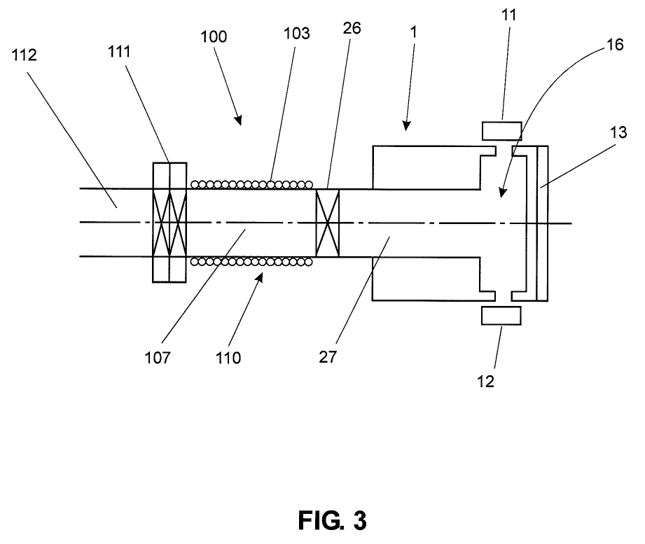

FIG. 1 is a schematic of an exemplary ion source for use with the present invention. The ion source is described in detail in U.S. Pat. No. 7,107,929, hereby incorporated by reference. FIG. 2 is a schematic of an embodiment of a gas reaction chamber in accordance with the present invention and a traditional vaporizer feeding an ionization chamber. FIG. 3 is a schematic of an embodiment of an ion source and an alternate embodiment of the gas reaction chamber in accordance with the present invention

Referring to FIG. 1, the ion source, generally identified with the reference numeral 1, includes a low temperature vaporizer (as opposed to a high temperature oven). The vaporizer 2 is attached to a vaporizer valve 3 through an annular thermally conductive gasket 4. The vaporizer valve 3 is likewise attached to a mounting flange 7, which, in turn, is attached to an ionization chamber body 5 by further annular thermally conductive gaskets 6 and 6A. This ensures good thermal conduction between the vaporizer, vaporizer valve, and ionization chamber body 5 through intimate contact via thermally conductive elements. The mounting flange 7 attached to the ionization chamber 5, e.g., allows mounting of the ion source 1 to the vacuum housing of an ion implanter, and contains electrical feedthroughs (not shown) to power the ion source, and water-cooling feedthroughs 8, 9 for cooling. The exit aperture plate 13 is mounted to the face of the ionization chamber body 5 by metal screws (not shown).

When the vaporizer valve 3 is in the open position, vaporized gases from the vaporizer 2 flow through the vaporizer valve 3 to an inlet channel 15 into the open volume of an ionization chamber 16. These gases are ionized, for example, by interaction with the electron beam transported from an electron source 12 to an electron beam dump 11. The ions produced in the ionization chamber 16 exit the ion source 1 by way of an exit aperture 37, where they are collected and transported by the ion optics of the ion implanter in a manner generally known in the art.

The body of vaporizer 2 houses a liquid, e.g., water bath 17 which surrounds a crucible 18 containing a solid feed material. The water bath 17 is heated by a resistive heater plate 20 and cooled by a heat exchanger coil 21 to keep the water bath at the desired temperature. The heat exchanger coil 21 is cooled by de-ionized water provided by water inlet 22 and water outlet 23. The temperature difference between the heating and cooling elements provides convective mixing of the water, and a magnetic paddle stirrer 24 continuously stirs the water bath 17 while the vaporizer is in operation. A thermocouple 25 continually monitors the temperature of the crucible 18 to provide temperature readback for a PID) vaporizer temperature controller (not shown). The ionization chamber body 5 is made of aluminum, graphite, silicon carbide, or molybdenum, and operates near the temperature of the vaporizer 2 through thermal conduction. In addition to low-temperature vaporized solids, the ion source can receive gases through gas feed 26, which feeds directly into the open volume of the ionization chamber 16 by an inlet channel 27.

In order to operate with gaseous feed materials, ion implanters typically use gas bottles which are coupled to a gas distribution system within the ion implanter. The gases are fed to the ion source via metal gas feed lines which directly couple to the ion source 1 through a sealed gas fitting, such as a, VCR or VCO fitting.

FIG. 2 is an embodiment of the invention, showing a gas reaction chamber (or cracker) 100 intended to produce, e.g., tetramer molecules from a hydride feed gas. It is disposed next to a typical oven or vaporizer 2 known in the art, in a common dual configuration, similar to a configuration normally associated with 2 ovens or 2 vaporizers in which solid material is heated to provide a gas/vapor feed for the ion source. The vaporizer/oven 2 is used to sublimate, i.e. vaporize, solid materials which are into the ionization chamber 16 by way of the channel 15. The gas reaction chamber 100 is used for gaseous feed materials, such as gaseous hydrides.

In the embodiment illustrated in FIG. 2, the gas reaction chamber 100 includes an annular evacuated chamber 101 with a nozzle 102 feeding into the ionization chamber 16 of an ion source 1 not shown. In this embodiment, the gas reaction chamber 100 is heated by an external coil 103, which may be brazed onto the outer surface.

A control system, including a thermocouple 121, may be used to control the temperature of the gas reaction chamber 100 to temperatures greater than 800° C. by known temperature control systems, well known in the art. The gas reaction chamber 100 includes a gas feed inlet 104 which may be coupled to the semiconductor facility gas supply or a gas bottle (not shown). The gas distributed by the gas feed inlet 104 may be controlled by known gas control systems, also well known in the art.

Within the volume of the evacuated chamber 101 may be disposed a flow channeling device 105, formed, for example, in a cylindrical shape. The flow channeling device 105 may be fabricated from a metal, glass or a ceramic, such as, pyrolytic boron nitride, pBN. When the flow channeling device 105 is disposed within the evacuation chamber 101, an annular gas distribution plenum 120 is defined in fluid communication with the gas feed inlet 104. The inner diameter of the evacuation chamber 101 and the outer diameter of the flow channeling device 105 creates an annular gap or flow channel 107 for the gas from the annular gas distribution plenum 120 to allow the gas to uniformly distribute itself around the inner sidewalls of the evacuation chamber 101.

As shown in FIG. 2, heating coils 103 are disposed around the outside diameter of the evacuation chamber 101. These heating coils 103 are used to heat or “crack” the gas that is uniformly distributed in the flow channel 107. Since the gas is uniformly distributed in the flow channel 107, the gas is relatively uniformly heated. By uniformly heating the gas, the resulting species can be relatively accurately controlled by controlling the heating of the gas to include only the desired molecular or atomic species.

The flow channeling device 105 includes a longitudinal bore 106 that is in fluid communication with a nozzle 102 extending into the ionization chamber 16. As the gas is heated by the heating coils, the gas expands and flows into a cavity 110, formed between the inner wall 111 of the evacuation chamber 101 and the horizontal bore 106. The heated gas flows through the bore 106 and into the ionization chamber 16 by way of the nozzle 102.

The embodiment of the gas reaction chamber device 100, illustrated in FIG. 2, includes an evacuation chamber 101, a flow channeling device 105 and a nozzle 102. This embodiment includes a single configuration to convert a gaseous feed gas, such as a gaseous hydride, into another molecular or atomic species, e.g., conversion of a hydride feed gas into a tetramer gas for ionization. Other configurations are possible which cause the feed gas to be uniformly heated, as discussed above.

As is known in the prior art heating feed gases to specific temperatures can crack those gases to other molecular and atomic species. Temperatures for cracking various known source gases, such as gaseous hydrides, into other molecular and atomic species are generally known in the art, e.g., 200 degrees C. to 1000 degrees C.

As such, the gas reaction chamber 100 is adapted to breakup, “crack”, various molecular species, such as hydrides, e.g., AsH₃ or PH₃ into intermediate species which in the presence of the catalytic material conveniently form tetramers (AS₄ or P₄), dimers (As₂ or P₂) or other desirable monomer or molecular species, e.g., BF₃ to form BF₂ and/or B for implant in a single step without the use of a separate vaporizer oven.

Other gas species (including gas species other than hydrides), such as, BF₃, SbH₃, GeH₄, SiH₄ etc., may also be successfully processed in the gas reaction chamber 100 to form other desired molecular and atomic species. In general, the gas reaction chamber 100 in accordance with the present invention is configured to convert gaseous supply material, typically gases, of the form AₙCₘR_{z}Hₓ, where A is a dopant atom such as B, P, or As, C is carbon, R is a molecule, radical or ligand which contain atoms that are not injurious to the implantation process or semiconductor device performance, and H is hydrogen, n, m, x, and z are with n≧2, m≧0 and x and z≧0 into other desired molecular and atomic species for use in ion implantation.

In accordance with an important feature of the invention, the gas reaction chamber 100 may also be used to generate lower forms of gases passed therethrough. For example, the gas reaction chamber 100 may be configured to generate lower forms of BF₃ into lower forms, such as BF₂, BF and even B.

In a further embodiment of the invention, the gas reaction chamber device 100 may optionally include a catalytic material surface 108 shown here as disposed on or as part of the outside wall of the flow channeling device 105 and forming part of the flow surfaces of the flow channel 107 through which the feed gas communicates with the ion source chamber. Alternately, the catalytic material surface may form or be a part of any surface which the gas feed material comes into contact. In another alternate embodiment, a fine mesh of tungsten, W, may be inserted in to the flow channeling device 105 forming a convenient catalytic surface 108 allowing gas flow. In yet another alternate embodiment, thin sheets of metal may be used to form the catalytic surface 108. These metal sheets may be formed from various metals including tungsten, W, and molybdenum, Mo. The metal sheets forming the catalytic surface 108 are shaped to fit the flow channel 107.

In another alternate embodiment, the catalytic surface 108 material, such as tantalum, Ta, can be disposed within the bore 106. It is understood that many other materials can be used or in combination to form the catalytic material surface 108, such as stainless steel, pyrolytic boron nitride, graphite, refractory metals and quartz or a hot filament. In addition, the catalytic surface 108 may be formed in other shapes including mesh, solid surface, wires and wool.

The flow of gas through the gas reaction chamber 100 may be arranged alternatively to the configuration, illustrated in FIG. 2. For example, the gas reaction chamber 100 can be configured without a flow channeling device 105.ln one embodiment the heating coils 103 are not used. Baffles may also be used to control the pressure within the gas reaction chamber 100. Referring to FIG. 3, a schematic of a gas reaction chamber 100 without the channeling device 105 is illustrated. This gas reaction chamber 100 is formed as a simple conduit 110 connected to a gas supply 112 through one or more valves 111 at one end and to the ion source 1 at the other end via gas feed 26 and channel 27. The conduit 110 forms a flow channel 107 from the gas supply 112. The conduit 110 may be formed from a catalytic material 108 discussed above, a first material and a catalytic material, and/or a combination of catalytic materials or may include the catalytic material 108 inside the flow channel 107 (not shown) or lining or partially lining within the flow channel 107 (not shown) of the conduit 110.

In a further embodiment of the gas reaction chamber device 100, the gaseous feed material interacts with the catalytic material surface 108 in the presence of the heat from heating coils 103, wrapped around the conduit 110, converting the hydride or other gaseous feed material into a tetramer molecule or other specie, such as a dimer molecule. Alternatively the catalytic material itself may be heated by current flow (as in a filament) or inductively, thus providing a directly heated material distinct from the indirectly heated catalysts.

In operation, the gas feed material is allowed to flow through the reactor 100 on its way to the ionization chamber 16. The heating coils 103 are energized to raise the temperature of the gas reaction chamber 100, such that the gas feed material, for example; a gaseous hydride, is converted to the desired molecular or atomic species, for example, a tetramer molecule for ionization within the ion source 1. A temperature monitoring device (not shown) is used for closed loop control of the conduit temperature as discussed above.

In yet another embodiment of the invention, the gas reaction chamber 100 may be configured so that a catalytic (or pyrolytic) reaction occurs in the presence of an appropriate material including glass or metals, such as, W, Ta, Mo stainless steel, ceramics, boron nitride or other refractory metals, raised to an appropriate temperature, e.g., 600 degrees C. to 1000 degrees C., by the heating coils 103.

Obviously, many modifications and variations of the present invention are possible in light of the above teachings. Thus, it is to be understood that, within the scope of the appended claims, the invention may be practiced otherwise than as specifically described above.

What is claimed and desired to be secured by a Letters Patent of the United States is:

1. An ion source for use with an ion implant device, the ion source comprising:
an ionization chamber for receiving a feed gas, said ionization chamber having an extraction aperture for extracting ions of said feed gas,
a gaseous feed inlet for receiving a source of feed gas,
a gas reaction chamber in fluid communication with said gas feed inlet converts the feed gas into a useful specie, and
an ionization system which ionizes the feed gas the feed gas within ionization chamber and extracts ions of interest from said extraction aperture.

2. A method for converting a gaseous feed material into a different molecular or atomic species comprising the steps:
(a) receiving a source gas, and
(b) uniformly heating the source gas to produce a different molecular or atomic species as a function of the temperature of the source gas.

3. The method as recited in claim 2, further including step (c): reacting the source gas with a catalytic material.

4. The method as recited in claim 3, wherein step (c) comprises: reacting the source gas with a heated catalytic material.

5. The method as recited in claim 3, wherein step (c) comprises: reacting the source gas with an un-heated catalytic material.

6. The method as recited in claim 2, wherein step (c) comprises: reacting the source gas with a catalytic material in the presence of a refractory material.

7. The method as recited in claim 6, wherein step (c) comprises: reacting the source gas with a catalytic material in the presence of glass.

8. The method as recited in claim 6, wherein step (c) comprises: reacting the source gas with a catalytic material in the presence of a metal raised to a predetermined temperature.

9. The method as recited in claim 8, wherein step (c) comprises: reacting the source gas with a catalytic material in the presence of a metal raised to a predetermined temperature.

10. The method as recited in claim 8, wherein step (c) comprises: reacting the source gas with a catalytic material in the presence of W raised to a predetermined temperature.

11. The method as recited in claim 8, wherein step (c) comprises: reacting the source gas with a catalytic material in the presence of Ta raised to a predetermined temperature.

12. The method as recited in claim 8, wherein step c) comprises: reacting the source gas with a catalytic material in the presence of Mo raised to a predetermined temperature.

13. The method as recited in claim 8, wherein step (raised to a predetermined temperature c) comprises: reacting the source gas with a catalytic material in the presence of stainless steel raised to a predetermined temperature.

14. The method as recited in claim 8, wherein step (raised to a predetermined temperature c) comprises: reacting the source gas with a catalytic material in the presence of ceramic raised to a predetermined temperature.

15. The method as recited in claim 8, wherein step (raised to a predetermined temperature c) comprises: reacting the source gas with a catalytic material in the presence of boron nitride raised to a predetermined temperature.

16. A gas reaction chamber comprising:
an annular evacuation chamber having a gas feed inlet for receiving an external source of feed gas;
an annular flow channeling device configure to be received in said evacuation chamber forming a gas distribution plenum in fluid communication with said gas feed inlet and configured so that a flow channel is formed between the outer diameter of said flow channeling device and an inner diameter of said evacuation chamber, said annular flow channeling device including a longitudinal bore in fluid communication with said flow channel;
a nozzle in fluid communication with said longitudinal bore in fluid communication with said longitudinal bore and adapted to be in fluid communication with an ionization chamber; and
a heat source for heating said flow channel.

17. A gas reaction chamber comprising:
a conduit for receiving an external source of feed gas;
an inlet valve for coupling said conduit to an external source of feed gas;
an outlet valve for coupling said conduit to an ion source; and
a catalytic material disposed within said conduit for reacting with said feed gas.

18. The gas reaction chamber as recited in claim 17, further including a heat source for heating the feed gas within the conduit.

19. The gas reaction chamber as recited in claim 18, wherein said catalyst and heat source are configured so that said heat source is heated.

20. The gas reaction chamber as recited in claim 18, wherein said catalyst and heat source are configured so that said heat source is not heated.
